(19) United States
(12) Patent Application Publication
(10) Pub. No.: US 2007/0279037 A1
(43) Pub. Date: Dec. 6, 2007

(54) Spectrometry Diagnostic Electronic Circuit and Associated Counting System

(75) Inventors: Michel Jouve, Eguilles (FR); Didier Mazon, Manosque (FR)

Correspondence Address: Robert E Krebs;Thelen Reid & Priest, P O Box 640640, San Jose, CA, 95164-0640, US

(73) Assignee: COMMISSARIAT A L'ENERGIE ATOMIQUE, PARIS 15EME FRANCE (FR)

(21) Appl. No.: 10/589,112

(22) PCT Filed: Feb. 22, 2005
(86) PCT No.: PCT/FR05/50116

§ 371 Date: Aug. 7, 2007

(30) Foreign Application Priority Data
Feb. 24, 2004 (FR) 04/50338

(51) Int. Cl. G01R 29/027

(52) U.S. Cl. 324/76.12

(57) ABSTRACT

The invention relates to a spectrometry diagnostic electronic circuit comprising digital data detection means corresponding to detected pulses and amplitude measurement means to associate a measured amplitude with a detected pulse (24) , wherein pulse rejection means (25) are used to detect digital data and reject every pulse with a width that exceeds a pulse width threshold (tc) and any new pulse during a programmed time interval (T3), if a first pulse has been detected during the programmed time interval.

### TECHNICAL FIELD AND PRIOR ART

This invention relates to a spectrometry diagnostic electronic circuit.

The invention also relates to a particle counting system that includes a spectrometry diagnostic electronic circuit according to the invention. For example, the counting system may be a neutron counting system for a controlled nuclear fusion or fission reactor.

Controlled nuclear fusion is an attractive and inexhaustible alternative solution for the generation of electricity. The purpose of controlled fusion is to reproduce energy produced by the sun on earth. The energy is then produced inside a device commonly called a tokamak. A tokamak is a device that powerfully confines a very hot ionised gas ring called plasma, by the combined action of a strong magnetic field and an intense electric current of a few mega-amperes. The plasma develops deuterium/tritium fusion reactions within its body producing neutrons that carry energy. Optimisation of physical, technological and cost effectiveness constraints has lead to the definition of an “advanced tokamak” concept that consists of using stationary confinement conditions in which the entire current is generated non-inductively and largely by a current self-generated by the plasma commonly called a “bootstrap current”.

The use of “advanced tokamak” type regimes requires the capability of generating and controlling the bootstrap current. Among different known methods, injection of high power electromagnetic waves into plasma is a very high performance method for non-inductive generation of current in a tokamak. The power deposition profile of the electromagnetic waves then has to be controlled. Measurement of the emitted braking radiation within the range of hard X-rays by suprathermal electrons accelerated by the hybrid wave (mainly the electromagnetic wave that generates the non-inductive current in the Tokamak) is an efficient method of accessing information about the power deposition of the hybrid wave. For example, when controlling the current profile over long durations (see Peysson et al. “Revue of Science Instrument”, page 70, No. 10, 1999), the propagation and absorption of a hybrid wave are studied by using a high energy X tomography diagnostic with very high space and time resolutions. The tomographic system comprises a total of 59 lines of sight, the 59 detectors being distributed into two cameras, one horizontal and the other vertical, increasing the spatial redundancy of the measurements by forming a grid across the section of the plasma with lines of sights with very different inclinations. The diagnostic measures the emissivity of the plasma integrated along each line of sight, the main objective being to determine the radial emissivity profile of the plasma making use of all integrated measurements. This can be done by an Abel inversion method, provided that specific assumptions are satisfied.

FIG. 1 shows a principle diagram for a hard X-ray spectrometry diagnostic measurement system according to prior art.

The measurement system comprises a camera 1, a reception chassis 2, a bias circuit 3, a power supply circuit 4, a calibration circuit 5, a processing circuit 6 and a data storage unit 7. A switch 8 connects the output from the reception chassis 2 either to the input of the processing circuit 6 (in this case this is the measurement phase), or to the input of the calibration circuit 5 (in this case this is the calibration phase) The camera 1 comprises a detector 9 based on a Cadmium Tellurium (CdTe) semiconductor, a pre-amplifier 10 and a differential emitter 11. The reception chassis 2 comprises a differential receiver 12 and a linear amplifier 13. The bias circuit 3 polarises the detector, for example with a bias voltage equal to −100V. The power supply circuit 4 powers the electrical circuits 10 and 11 of the camera 1 and 12 and 13 of the reception chassis 2, for example with a +/−12V, 40 mA power supply. The processing circuit 6 comprises a set of discriminators D1 to D8, a set of counters C1 to C8 and a data acquisition unit 14.

The detector 9 is a physical medium in which the photons P emitted by the plasma transfer all or some of their energy. Energy transferred into the detector is converted into electrical pulses. Pulses from the detectors are then processed by an electronic counting system specially optimised for CdTe. Charge carriers are collected in the semiconductor by the preamplifier 10. The differential emitter 11 transmits the signal output by the preamplifier 10 through the differential receiver 12, to the linear amplifier 13 more commonly called the shaper. The function of the shaper is to transform the received pulses, usually with a fairly long relaxation time and that could consequently overlap if the count rate is too high, into relatively short pulses that are easy to count for the remainder of the acquisition system. The gain of the shaper may be adjusted manually for calibration of the signal energy.

During the measuring phase, the switch 8 connects the output from the reception chassis 2 to the input of the processing circuit 6. The received pulse height is then analysed by the eight integral discriminators D1-D8. The integral discriminators D1-D8 send logical signals to counters C1-C8 to which they are connected when the amplitude of the pulse rise front is greater than a discrimination threshold. Reception of the logical signal by a counter Ci (i=1, 2, . . . , 8) adds 1 to the buffer memory of the counter Ci that consequently contains the number of hits recorded with an energy greater than the discrimination threshold. For each sampling step (for example with a 16 ms step), the buffer memory of each counter is read and is then reset by the data acquisition unit 14 that transmits the eight count results into the data storage unit 7.

This system has several disadvantages.

Firstly there is no information concerning the input signal, so that the shaped pulse cannot be displayed and it becomes impossible to distinguish any piling up following the simultaneous arrival of two photons on the detector. Then, the measured signals are not available in real time which prevents any profile inversion in real time and consequently slaving of the deposited power of the hybrid wave and slaving of the current profile.

A calibration step is necessary to obtain reliable measurements. The output from the reception chassis 2 is then connected to the input of the calibration circuit 5.

Calibration consists of adjusting the gain of the shaper circuit so as to get good correspondence between the amplitude of the pulse output by the reception chassis 2 and the energy of the incident photon. As was mentioned above, the tomographic system known in the art includes two cameras, one vertical and the other horizontal, comprising 21 detectors for the vertical camera and 38 detectors for the horizontal camera giving a total of 59 detectors. Calibration is then done for each detector.

Calibration is essential to be able to obtain precise reconstruction of X emissivity profiles in the different energy channels. Calibration can then be done using a digital spectrometer with 1024 channels and using three radioactive sources. The gain of the shaper is then adjusted so as to place the main peak of each source at the right energy.

The calibration step also has disadvantages. It requires that some of the electronics of the acquisition system be disconnected, and is then not used in the calibration. This can result in calibration errors. Furthermore, this disconnection increases the manipulations made on the system and consequently the risks of damaging it. Furthermore, camera 1 is remote from the acquisition system to which the calibration bench is connected. This obliges the operator to do many forward and return operations when he has to modify the position of the source with respect to the camera.

The spectrometry diagnostic electronic circuit according to the invention does not have the disadvantages mentioned above.

### PRESENTATION OF THE INVENTION

The invention relates to a spectrometry diagnostic electronic circuit comprising digital data detection means corresponding to detected pulses and amplitude measurement means to associate a measured amplitude with a detected pulse. The diagnostic electronic circuit includes pulse rejection means that uses the detected digital data and rejects a pulse with a width that exceeds a pulse width threshold and any new pulse during a programmed time interval if a first pulse has been detected during the programmed time interval.

According to another characteristic of the invention, the spectrometry diagnostic electronic circuit comprises calibration means including a histogram memory to sort digital data corresponding to the detected pulses that were not rejected by the pulse rejection means, by calibration energy range when the detected pulses originate from a standard source.

According to yet another characteristic of the invention, the electron spectrometry diagnostic circuit comprises:
sort means, to sort firstly all detected pulses and secondly detected pulses that were not rejected by the pulse rejection means, by detection energy ranges, and
count means to count firstly all detected pulses and secondly detected pulses that were not rejected by the pulse rejection means, by detection energy ranges.

According to yet another characteristic of the invention, the spectrometry diagnostic electronic circuit includes at least one circular memory that stores digital data at a configurable rate.

According to yet another characteristic of the invention, the spectrometry diagnostic electronic circuit includes means for excluding pulses for which the measured amplitude is less than an amplitude threshold value.

According to yet another characteristic of the invention, the spectrometry diagnostic electronic circuit includes at least one input amplifier to amplify detected analogue pulses and at least one analogue/digital converter to convert the detected analogue pulses into said digital data.

According to yet another characteristic of the invention, the circular memory memorises the history of data output from the analogue/digital converter.

The invention also relates to a particle counting system including particle detection means to form detected pulses and means of processing the detected pulses. The processing means include a spectrometry diagnostic electronic circuit according to the invention.

According to another characteristic of the invention, the processing means include a shared random access memory connected to a communication network.

According to another characteristic of the invention, the particles are hard X-rays.

The pulse rejection means of the diagnostic electronic circuit according to the invention have many advantages. When combined with the calibration means according to the invention, they enable the use of an in situ calibration without disassembling or disconnecting the measurement system, which very significantly reduces risks of errors. It is then possible to perform high quality calibrations in a hostile medium in a routine manner. The calibration may relate to all sight channels. Also, in combination with the sorting and counting means according to the invention, the pulse rejection means according to the invention can be used to implement real time discrimination and counting of the detected pulses. Real time measurement of the detected pulses has the main advantage that a suitable program can be used to obtain a local emissivity profile by inversion of real time data using an Abel method. Suprathermal profiles can then be slaved, consequently enabling direct control over the current profile, which satisfies the fixed objective for an “advanced tokamak”.

### BRIEF DESCRIPTION OF THE DRAWINGS

Other characteristics and advantages of the invention will become clearer after reading a preferred mode for carrying out the invention with reference with the appended figures, wherein:

FIG. 1 shows a hard X-ray spectrometry diagnostic measurement system according to prior art;

FIG. 2 shows a spectrometry diagnostic measurement system according to the invention;

FIG. 3 shows a block diagram of an example of a diagnostic electronic circuit according to the invention;

FIG. 4 shows a typical pulse representation as it arrives at the input to a diagnostic electronic circuit according the invention;

FIG. 5 shows a detailed diagram of an example of a processing channel for a diagnostic electronic circuit according to the invention;

FIG. 6 shows a calibration histogram obtained using a diagnostic electronic circuit according to the invention;

FIG. 7 shows a block diagram of an improvement to the diagnostic electronic circuit according to the invention shown in FIG. 3;

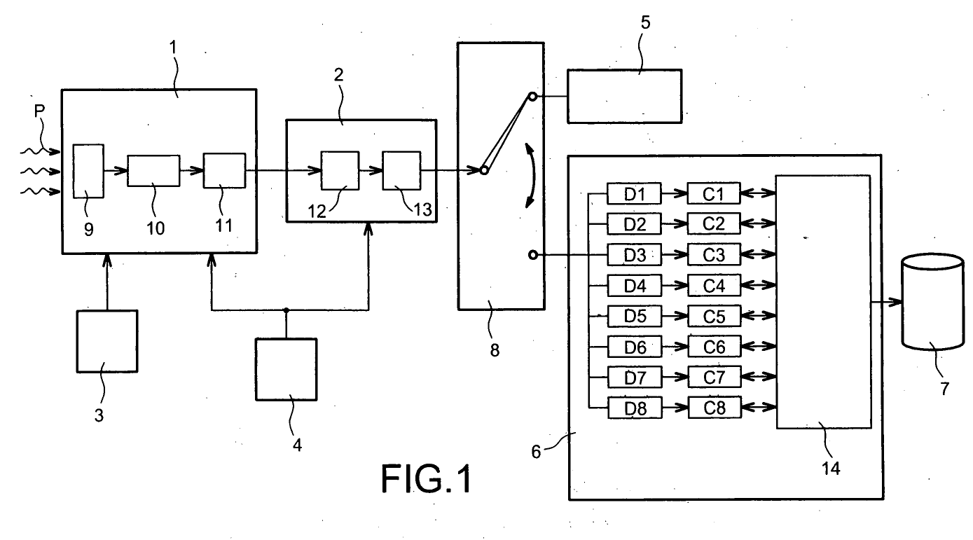

The same marks denote the same elements in all the figures.

### DETAILED DESCRIPTION OF EMBODIMENTS OF THE INVENTION

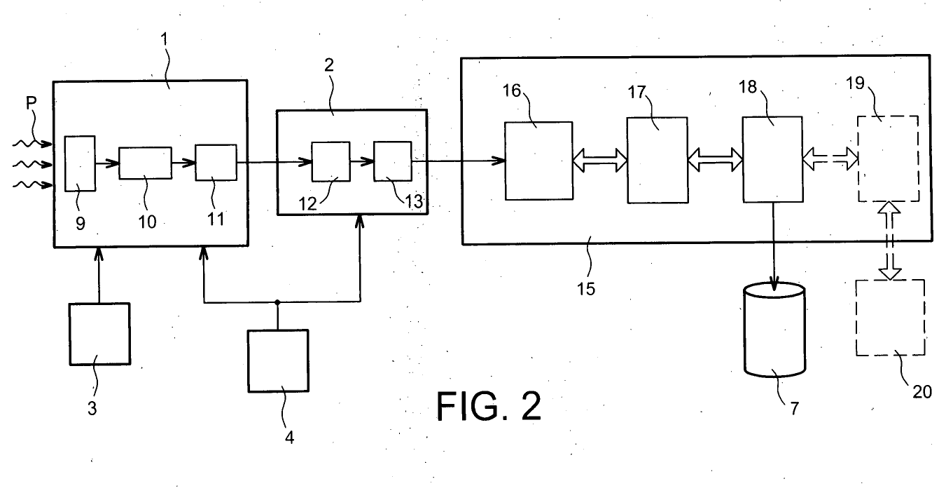

FIG. 2 shows a spectrometry diagnostic measurement system based on radiation, for example of hard X-rays, according to the invention, for one channel.

The measurement system includes a camera 1, a reception chassis 2, a bias circuit 3, a power supply circuit 4, a data processing circuit 15 and a data storage unit 7. The measurement system according to the invention is different from the measurement system according to prior art due to the data processing circuit 15. The data processing circuit 15 includes a diagnostic electronic circuit 16 according to the invention in series with a data acquisition and processing unit 17 and a management unit 18. According to one improvement to the invention, the data processing circuit 15 may also contain a shared RAM 19. The shared RAM 19, for example a SCRAMNET (Shared Common Random Access Memory Network) card can then advantageously be used to share data with other acquisition units through a communication network 20.

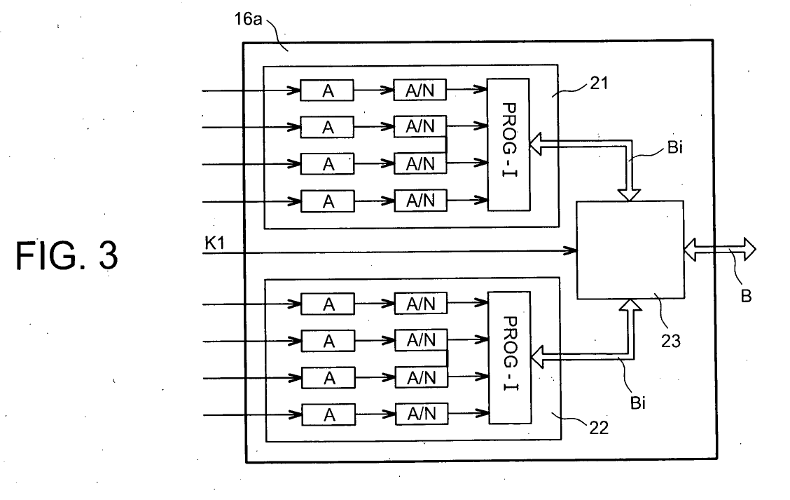

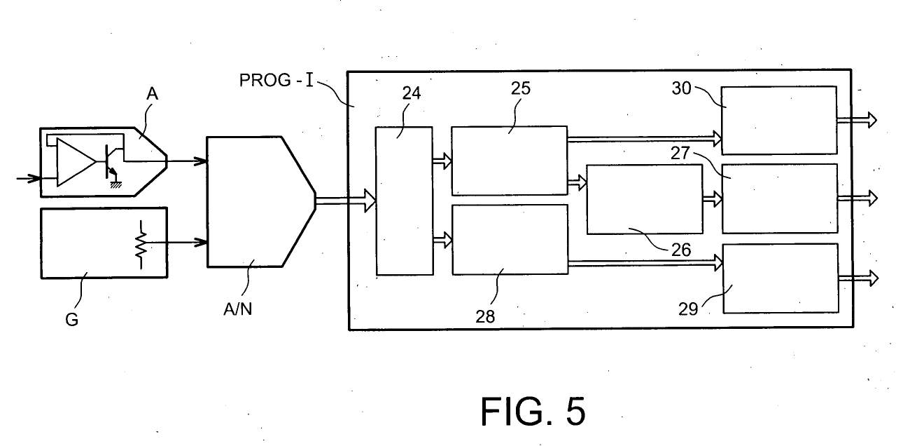

FIG. 3 shows a block diagram of an example electronic diagnostic circuit 16a according to the invention. The processing circuit 16a includes two data processing modules 21, 22 and a programmable interface and control logic component 23. Each data processing module 21, 22 is connected to the programmable interface and control logic component 23 through a bus Bi internal to the card. A data processing module includes for example four input amplifiers A in parallel, four analogue/digital converters A/N mounted in series with the four input amplifiers and a programmable pulse processing logic component PROG-I. The programmable interface and control logic component 23 is controlled by a control K1 that controls the data acquisition rate. A VME (Virtual Machine Electronic) bus B connects the programmable interface and control logic component 23 to the data acquisition and processing unit 17 (not shown in FIG. 3) that is also connected to the control unit 18 (not shown in FIG. 3) through the same VME bus B. Each programmable pulse processing logic component PROG-I applies a set of operations on the digital data that it receives, that are presented in more detail below in the description of FIG. 5.

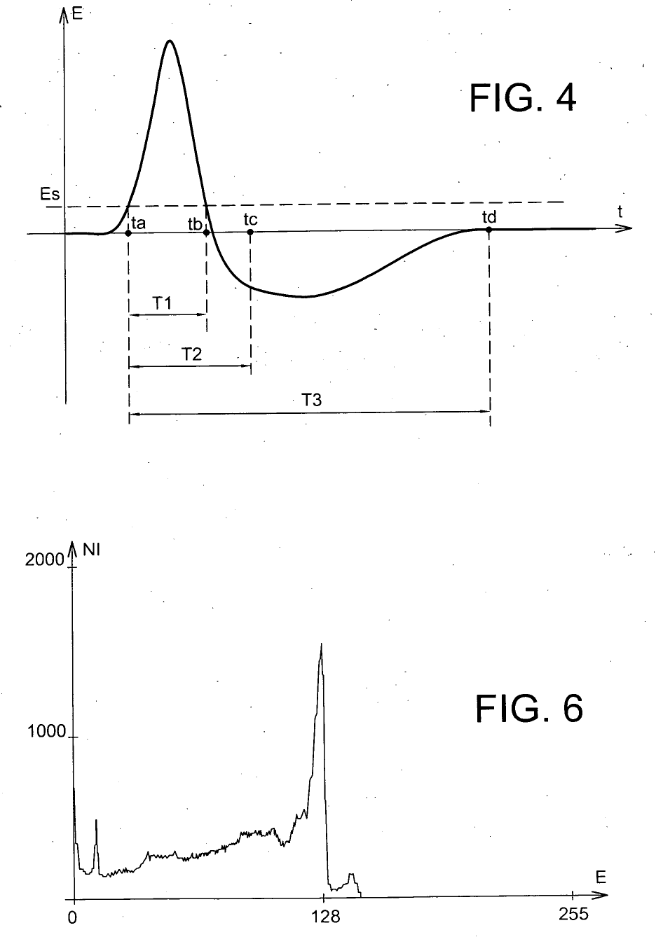

FIG. 4 is a typical representation of the signal as it arrives at the input to the diagnostic electronic circuit according to the invention, and FIG. 5 shows a detailed diagram of a signal processing channel shown in FIG. 4.

The curve in FIG. 4 shows the energy E of the signal as a function of time t. The curve of the energy E comprises a positive pulse shaped part and a negative part. The “useful” part of the signal is the positive part. The duration of the positive part is of the order of one microsecond. The negative part, for which the duration is of the order of a few microseconds (typically 3 or 4 μs) is due to the processing electronics. Several time parameters are shown in FIG. 4 (ta, tb, tc, td, T1, T2, T3) that will be explained in the remainder of the description.

FIG. 5 shows a detailed diagram of a processing channel 21, 22.

A processing module 21, 22 includes several processing channels. FIG. 5 only shows a single processing channel composed of an input amplifier A, a single analogue/digital converter A/N, a gain adjustment circuit G of the converter and the associated fraction of the programmable pulse processing logic component PROG-I, for reasons of convenience in order to not encumber the figure.

The component PROG-I includes the following functional modules:
a pulse detection and detected pulse amplitude measurement module 24,
a pile-up rejection module 25,
two sort modules 26, 28 by energy range,
two digital counter modules 27, 29 and
a histogram memory 30.

Apart from the amplification function, the input amplifier A performs an impedance matching function and deletes the negative part of the received signal (see FIG. 4). The analogue digital converter A/N quantifies the signal output from the amplifier A. The gain adjustment circuit G programs the gain of the converter through a VME bus. The converter gain is programmed during the calibration step. The processing module 24 firstly detects pulses and secondly measures the amplitude of the pulses. According to one preferred embodiment of the invention, a pulse energy threshold Es is used during the detection, in order to make the measurement independent of noise (see FIG. 4). Pulses for which the energy level is greater than or equal to the threshold Es are taken into account while pulses with a lower energy level are eliminated. When a pulse is taken into account, its width T1 is measured (see FIG. 4). The start time from which a pulse width is measured is the time ta beyond which the pulse energy increases beyond the threshold Es. The time tb from which the amplitude of the pulse drops below the threshold Es is then used to define the pulse width T1 that is written as follows:
T1=tb−ta

A pulse width time threshold tc is used to sort pulses as a function of their width. The maximum width T2 of a pulse (T2=tc−ta) may for example be equal to 1.5 μs.

The start time ta from which the pulse width is measured is also the starting point for a programmable time T3 during which any new pulse is not counted. The time T3 may for example be equal to 5 μs. The programmable time td that limits the delay T3 (T3=td−ta) may for example correspond to the time at which the source pulse, in other words the pulse before its negative part is deleted, returns to substantially zero (see FIG. 4).

The pile-up rejection module 25 rejects any pulse with a width that exceeds the pulse width threshold tc, and rejects any new pulse after a first pulse has been detected during a programmed time interval, for example the interval T3. Pulses that are not rejected by the pile-up rejection module 25 are accepted and sorted by programmable energy ranges (sort module 26). For example, the following energy ranges can be used:
[20 kev-40 kev[,
[40 kev-60 kev[,
[60 kev-80 kev[,
[80 kev-100 kev[,
[100 kev-120 kev[,
[120 kev-140 kev[,
[140 kev-160 kev[,
≧160 kev.

Pulses in each energy range are then counted in the count module 27. For example, in the case in which there are eight energy ranges as mentioned above, the count module 27 may include eight 12-bit counters, in other words one counter per energy range. Only the counter associated with the energy range detected for the current pulse is incremented.

Detected pulses that have been rejected are also sorted by energy ranges such that all detected pulses are also sorted (sort module 28) and counted (count module 29).

The histogram memory 30 is used during calibration measurements. The spectrometry diagnostic electronic circuit is then put into calibration mode.

The calibration method will now be described. A data acquisition is started from a known external stimulus (standard source). The histogram memory 30 sorts the signal by range of calibration energy. For example, the calibration energy range may be of the order of 1 keV. Only pulses sorted after pile-up rejection are considered in this calibration. Each pulse input into the histogram memory increments a memory box corresponding to the maximum amplitude of its energy. A search can then be made to find the box or group of boxes in which the largest number of pulses occurs. The gain can then be adjusted through the VME bus to make this maximum coincide with the expected known energy of the standard source.

FIG. 6 shows an example of the content of a histogram memory. The abscissa shows the different energy levels E and the ordinate shows the number NI of pulses collected for each energy level.

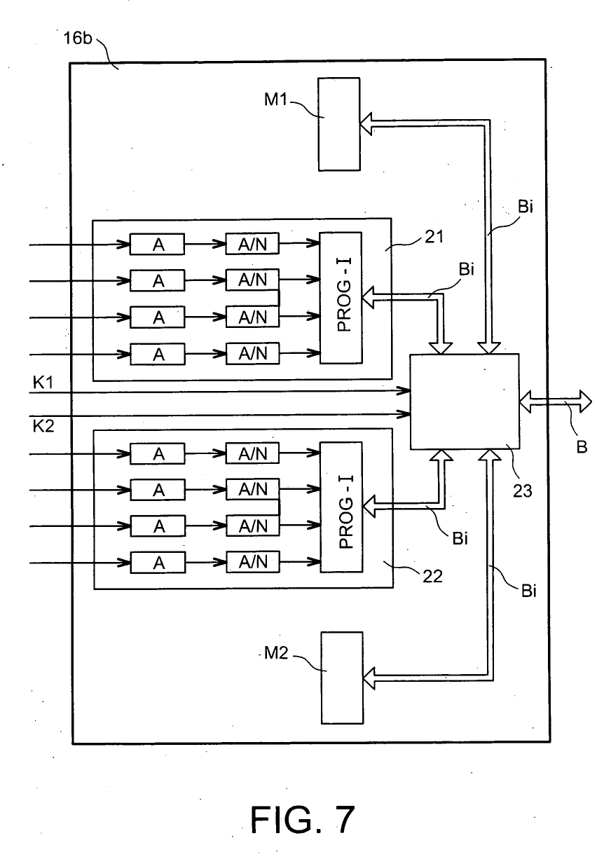

FIG. 7 shows a spectrometry diagnostic electronic circuit according to one improvement to the invention.

The diagnostic electronic circuit according to the improvement to the invention includes two circular buffer memories M1 and M2, in addition to the elements described above with reference to FIG. 3, that receive on their inputs digital data output by the corresponding processing modules 21 and 22. An internal bus Bi connects each circular memory M1, M2 to the programmable interface and control logic component 23. A control K2 applied to the programmable logic component 23 starts storage of data output from the processing modules 21 and 22 into the corresponding circular memories M1 and M2. For example, the circular memories M1 and M2 store the history of data output from the A/N converters included in the corresponding processing modules 21 and 22, at a rate that can be configured through the VME bus B, or they can store the history of state changes of counters 27, 29 at a configurable rate through bus B, this rate possibly being higher than the basic acquisition rate so that changes in counters between two acquisitions can thus be observed.

1. Spectrometry diagnostic electronic circuit comprising digital data detection means corresponding to detected pulses and amplitude measurement means to associate a measured amplitude with a detected pulse (24), wherein pulse rejection means (25) use detected digital data to reject every pulse with a width that exceeds a pulse width threshold (tc) and any new pulse during a programmed time interval (T3), if a first pulse has been detected during the programmed time interval.

2. Spectrometry diagnostic electronic circuit set forth in claim 1, wherein calibration means include a histogram memory (30) to sort digital data corresponding to the detected pulses that were not rejected by the pulse rejection means, by calibration energy range when the detected pulses originate from a standard source.

3. Spectrometry diagnostic electronic circuit set forth in claim 1 wherein:
sort means (28, 26) sort firstly all detected pulses and secondly detected pulses that were not rejected by the pulse rejection means, by detection energy range (25), and
count means (29, 27) count firstly all detected pulses and secondly detected pulses that were not rejected by the pulse rejection means, by detection energy range (25).

4. Spectrometry diagnostic electronic circuit according to claim 1, wherein at least one circular memory (M1, M2) stores digital data at a configurable rate (K2).

5. Spectrometry diagnostic electronic circuit according to claim 1, wherein means for excluding pulses exclude pulses for which the measured amplitude is less than an amplitude threshold value (Es).

6. Spectrometry diagnostic electronic circuit according to claim 1, wherein at least one input amplifier (A) amplifies detected analogue pulses and at least one analogue/digital converter (A/N) converts the detected analogue pulses into said digital data.

7. Spectrometry diagnostic electronic circuit set forth in claim 6, wherein the circular memory (M1, M2) memorises the history of data output from the analogue/digital converter (A/N).

8. Particle counting system including particle detection means to form detected pulses and means (15) of processing the detected pulses, wherein the processing means (15) include a spectrometry diagnostic electronic circuit comprising digital data detection means corresponding to detected pulses and amplitude measurement means to associate a measured amplitude with a detected pulse (24), wherein pulse rejection means (25) use detected digital data to reject every pulse with a width that exceeds a pulse width threshold (tc) and any new pulse during a programmed time interval (T3), if a first pulse has been detected during the programmed time interval.

9. Particle counting system set forth in claim 8, wherein the processing means (15) include a shared random access memory (19) connected to a communication network (20).

10. Particle counting system set forth in claim 8, wherein the particles are hard X-rays.
